(19) United States
(12) Patent Application Publication
(10) Pub. No.: US 2026/0228391 A1
(43) Pub. Date: Aug. 6, 2026

(54) Generative Adversarial Agentic Architecture for Automated Parametric Computer-Aided Design Modeling and Multi-Physics Simulation Optimization

(71) Applicant: ABB Schweiz AG, Baden (CH)

(72) Inventors: Matthew Hetrich, Cary, NC (US); Stefan Rakuff, Garner, NC (US); Premith Kumar Chilukuri, Raleigh, NC (US)

(73) Assignee: ABB Schweiz AG, Baden (CH)

(21) Appl. No.: 19/045,900

(22) Filed: Feb. 5, 2025

(51) Int. Cl. G06F 30/27; G06F 30/10

(52) U.S. Cl. CPC G06F 30/27; G06F 30/10

(57) ABSTRACT

A modeling plan that includes code for geometric modeling software is generated based on a reasoning paradigm that uses information as input, the information obtained from sources and identifying geometric dimensions and relations for a CAD modeling process for an object. A CAD model is generated for the object using the generated code and defects or errors in the CAD model are identified to generate feedback. The modeling plan is updated and updated code is generated in response to receiving the feedback to generate an updated CAD model for the object. Simulation boundary conditions for multi-physics simulations are generated based on the updated CAD model and the information. Simulation code is generated for simulation software to execute a numerical analysis based on the simulation boundary conditions and the updated CAD model. Simulation results are generated by executing the simulation code and functional defects in the updated CAD model are identified.

### FIELD

The present disclosure relates to a method and system for using multiple machine learning agents to model, validate, and optimize three dimensional (3D) parametric computer-aided designs.

### BACKGROUND

Large Language Models (LLMs) are sophisticated neural network-based models that have revolutionized the field of Natural Language Processing (NLP) and Artificial Intelligence (AI). These models are trained on vast amounts of textual data to learn statistical patterns and context-based relationships between words. LLMs can generate human-like text, perform reasoning tasks, and engage in sophisticated dialogues. The domains of Computer-Aided Design (CAD) modeling and multi-physics simulations often rely on manual input and iterative refinement by human engineers or designers, which can be time-consuming and error-prone.

### SUMMARY

An embodiment of the present disclosure provides a computer-implemented method for parametric computer-aided design (CAD) modeling using an Agentic Architecture implemented by one or more processors, the method including obtaining, by a criterion agent, information from one or more sources to determine geometric dimensions and relations for a CAD modeling process for an object; generating, by a modeling agent, a modeling plan that includes code for geometric modeling software based at least in part on a reasoning paradigm that uses the information as input, the generated code used to generate a CAD model for the object; identifying, by a discriminating modeling agent, defects or errors in the CAD model to generate feedback for the modeling agent, the feedback used to generate updated code for an updated CAD model for the object; generating, by a simulation criterion agent, simulation boundary conditions for multi-physics simulations based on the updated CAD model and the information from the criterion agent; generating, by a simulation agent, simulation code for simulation software to execute a numerical analysis based on the simulation boundary conditions and the updated CAD model for the object, the simulation code executed to generate simulation results; identifying, by a discriminating simulation agent, functional defects in the updated CAD model based on the simulation results; and updating, by the modeling agent, the updated CAD model based on the functional defects identified by the discriminating simulation agent.

In an embodiment, the method further includes updating, by the modeling agent, the modeling plan and generating the updated code for the geometric modeling software in response to receiving the feedback from the discriminating modeling agent to generate the updated CAD model for the object, wherein the simulation agent generates the simulation results by executing the simulation code via the simulation software, and wherein updating the CAD model is performed iteratively until the discriminating model agent does not identify the defects or errors in the updated CAD model.

In an embodiment, updating the updated CAD model is performed iteratively until the discriminating simulation agent does not identify the functional defects in the updated CAD model based on the simulation results.

In an embodiment, the method further includes updating the modeling agent based on the feedback and the simulation agent based on the identified functional defects in the updated CAD model.

In an embodiment, the criterion agent, the modeling agent, the discriminating modeling agent, the simulation criterion agent, the simulation agent, and the discriminating simulation agent are each a separate large langue model (LLM) or vision language model (VLM).

In an embodiment, the one or more sources includes text, images, technical drawings, forms, parameters, or metrics obtained by a user or from one or more data bases.

In an embodiment, the criterion agent is configured to obtain the information from the user via an interactive chat generated and iteratively updated by the criterion agent in response to receiving user provided input.

In an embodiment, the modeling agent generates the modeling plan that includes the code for the geometric modeling software by implementing reasoning paradigms.

In an embodiment, the reasoning paradigms include Reasoning+Acting (ReACT), Chain of Thought (CoT), and Tree-of-Thought reasoning paradigms.

In an embodiment, the method further includes instructing one or more fabrication process machines to generate the object using the updated CAD model.

In an embodiment, updating, by the modeling agent, the updated CAD model based on the functional defects identified by the discriminating simulation agent includes changing parameters, data points, or measurements in a file corresponding to the updated CAD model.

An embodiment of the present disclosure provides a computer system for parametric computer-aided design (CAD) modeling using an Agentic Architecture, the computer system including one or more hardware processors which, alone or in combination, are configured to provide for execution of the following steps: generating, by a modeling agent, a modeling plan that includes code for geometric modeling software based at least in part on a reasoning paradigm that uses information as input, the information obtained from one or more sources and identifying geometric dimensions and relations for a CAD modeling process for an object; generating a CAD model for the object using the generated code; identifying, by a discriminating modeling agent, defects or errors in the CAD model to generate feedback for the modeling agent; updating, by the modeling agent, the modeling plan and generating updated code for the geometric modeling software in response to receiving the feedback from the discriminating modeling agent to generate an updated CAD model for the object; generating, by a simulation criterion agent, simulation boundary conditions for multi-physics simulations based on the updated CAD model and the information from the criterion agent; generating, by a simulation agent, simulation code for simulation software to execute a numerical analysis based on the simulation boundary conditions and the updated CAD model for the object; generating, by the simulation agent, simulation results by executing the simulation code via the simulation software; identifying, by a discriminating simulation agent, functional defects in the updated CAD model based on the simulation results; and updating, by the modeling agent, the updated CAD model based on the functional defects identified by the discriminating simulation agent.

In an embodiment of the computer system, updating the CAD model is performed iteratively until the discriminating model agent does not identify the defects or errors in the updated CAD model.

In an embodiment of the computer system, updating the updated CAD model is performed iteratively until the discriminating simulation agent does not identify the functional defects in the updated CAD model based on the simulation results.

In an embodiment of the computer system, the steps further including updating the modeling agent based on the feedback and the simulation agent based on the identified functional defects in the updated CAD model.

In an embodiment of the computer system, the one or more sources includes text, images, technical drawings, forms, parameters, or metrics obtained by a user or from one or more data bases.

In an embodiment of the computer system, the modeling agent generates the modeling plan that includes the code for the geometric modeling software by implementing reasoning paradigms.

An embodiment of the present disclosure provides a tangible, non-transitory computer-readable medium having instructions thereon which, upon being executed by one or more processors, provide for parametric computer-aided design (CAD) modeling using an Agentic Architecture by execution of the following steps: obtaining, by a criterion agent, information from one or more sources to determine geometric dimensions and relations for a CAD modeling process for an object; generating, by a modeling agent, a modeling plan that includes code for geometric modeling software based at least in part on a reasoning paradigm that uses the information as input; generating a CAD model for the object using the generated code; identifying, by a discriminating modeling agent, defects or errors in the CAD model to generate feedback for the modeling agent; updating, by the modeling agent, the modeling plan and generating updated code for the geometric modeling software in response to receiving the feedback from the discriminating modeling agent to generate an updated CAD model for the object; generating, by a simulation agent, simulation code for simulation software to execute a numerical analysis based on simulation boundary conditions and the updated CAD model for the object, the simulation boundary conditions being for multi-physics simulations based on the updated CAD model and the information from the criterion agent; generating, by the simulation agent, simulation results by executing the simulation code via the simulation software; identifying, by a discriminating simulation agent, functional defects in the updated CAD model based on the simulation results; and updating, by the modeling agent, the updated CAD model based on the functional defects identified by the discriminating simulation agent.

In an embodiment of the tangible, non-transitory computer-readable medium, the instructions, upon being executed by the one or more processors, are further configured to execute the following steps of updating the modeling agent based on the feedback and the simulation agent based on the identified functional defects in the updated CAD model.

In an embodiment of the tangible, non-transitory computer-readable medium, the instructions, upon being executed by the one or more processors, are further configured to execute the following steps of instructing one or more fabrication process machines to generate the object using the updated CAD model.

### BRIEF DESCRIPTION OF THE DRAWINGS

The present disclosure will be described in even greater detail below based on the exemplary figures. The disclosure is not limited to the exemplary embodiments. All features described and/or illustrated herein can be used alone or combined in different combinations in embodiments of the disclosure. The features and advantages of various embodiments of the present disclosure will become apparent by reading the following detailed description with reference to the attached drawings which illustrate the following:

FIG. 1 illustrates an example architecture for parametric computer-aided design (CAD) modeling using an Agentic Architecture according to embodiments described herein;

FIG. 2 illustrates an example architecture for parametric computer-aided design (CAD) modeling using an Agentic Architecture including one or more agents according to embodiments described herein;

FIG. 3 illustrates an example flow chart for implementing vision language models for the parametric computer-aided design (CAD) modeling using an Agentic Architecture according to embodiments described herein embodiments described herein;

FIG. 4 illustrates an example architecture for parametric computer-aided design (CAD) modeling and a Finite Element Analysis (FEA) using an Agentic Architecture including one or more agents or modules according to embodiments described herein;

FIGS. 5A and 5B illustrate a flow chart for parametric computer-aided design (CAD) modeling using an Agentic Architecture according to embodiments described herein; and

FIG. 6 illustrates a simplified block diagram of one or more devices or systems for parametric computer-aided design (CAD) modeling using an Agentic Architecture according to embodiments of the present disclosure.

### DETAILED DESCRIPTION

Embodiments of the present disclosure provide a method and system for parametric computer-aided design (CAD) modeling using an Agentic Architecture. While the present disclosure is described primarily in connection with machines, systems, or components operated in an industrial setting or environment, such as machines or systems associated with programmable logic controllers (PLCs), fabrication process machines, as would be recognized by a person of ordinary skill in the art, the disclosure is not so limited and inventive features apply to other components or systems which use computer aided models to produce, fabricate, or generate objects.

The current landscape of 3D CAD modeling and multi-physics simulation faces multiple substantial challenges including the use of manually intensive processes, i.e., traditional CAD modeling requires substantial human input which can lead to errors and inefficiencies. Engineers often spend a considerable amount of time creating and modifying 3D models and assemblies with the result being highly dependent upon their expertise. Manually created models are often rigid and time consuming to modify (e.g. understanding requirements, deployment environments, chemical impacts, thermal cycling Geometric Dimensioning and Tolerancing (GD&T), as-assembly procedures, etc.), especially when object dimensions and tolerances are interdependent on other components. These sequential manual requirements constrain and limit design processes and innovation. Conventional processes have inadequate integration with numerical simulations (i.e. Finite Element Analysis (FEA)). Simulation like tools currently available for CAD modeling are often cumbersome when using the CAD-first design software and updates to models are not properly propagated to other software requiring many manual steps and leading to delayed feedback loops. Moreover, defining appropriate boundary conditions for numerical simulations can be complex and require domain-specific and often esoteric expertise. This complexity may lead to erroneous results, suboptimal designs, and increased development times. Conventionally, the process of refining designs based on simulation outputs is often manual and consumes a larger amount of time and computer resources. Engineers typically must adjust design parameters and re-run simulations, which can be a labor-intensive and error-prone process, or set up limited macros with limited analytical intelligence. This can lead to many simulation runs of only slight permutations that do not cover a sufficient parameter space.

According to aspects of the present disclosure, a novel agentic architecture that leverages and enhances LLM reasoning capabilities is described which provides solutions to problems associated with conventional CAD modeling and fabrication techniques, such as those described above. For example, the agentic architecture features described herein can model, validate, and optimize 3D parametric CAD designs in an efficient and accurate manner that saves time and reduces computer resource usage associated with inefficient manual interaction. The system described herein, in embodiments, includes multiple agents working in a coordinated manner. For example, a criterion agent may gather contextual information from various inputs, including but not limited to two-dimensional (2D) sketches, natural language descriptions, application programming interface (API) data, user input/discussions, etc., and converts the contextual inputs into a unified representation. The unified representation may be a unified latent space, domain conversion to natural language, specific data structure, or other suitable representation. The criterion agent may implement reasoning paradigms to accomplish this goal and ensure that all criteria provided as input reflect a real-world use case that is aligned with user requirements. This can help create designs that are not only technically sound and feasible but that are also commercially viable.

In embodiments, a modeling agent may receive the unified data structure from the criterion agent. The modeling agent may then employ various reasoning paradigms such as Reasoning+Acting (ReACT), Chain of Thought (CoT), and Tree-of-Thought reasoning paradigms to generate a step-by-step sequential modeling plan. The advanced reasoning paradigms enable the modeling agent to reason through complex scenarios and make informed design decisions. The modeling agent may then execute the modeling plan in a virtual environment using CAD modeling libraries and API calls, ensuring that the model is generated with best practices. For example, an LLM implementing the modeling agent may be domain adapted to a respective organization's best modeling procedures, through continued-pre-training (CPT), and/or supervised fine-tuning (SFT), for a parametric and easily editable model. The generated 3D model may then be provided as input to a discriminating modeling agent (also referred to as a modeling discriminator agent) that is also implemented by an LLM optimized (again via CPT/SFT, prompt engineering, and/or structured output (grammars)) for critiquing 3D parametric CAD models. The discriminating modeling agent may interpret or analyze the CAD model through a reasoning paradigm while recursively or hierarchically reasoning deeper as needed to provide critical feedback for the modeling agent regarding geometric accuracy, structural integrity, adherence to design specifications, etc. The generating and discriminating process continues iteratively in a similar fashion to generative adversarial networks (GANs) but for a reasoning task until the discriminating modeling agent can no longer critique the modeling agent's design.

The modeling discriminator agent's validated design (i.e., accepted CAD model) is then provided to a Simulation Generating Agent (also referred to as a Simulation Agent), which takes as input any additional requirements gathered by the Criterion Agent (also referred to as a Simulation Criterion Agent) or other input source and sets up the necessary multi-physics simulations including appropriate boundary conditions and parameters. This is also implemented through an internal reasoning paradigm that checks its own work while progressing. The Simulation Generating Agent may then execute virtual code, including executing API calls to an appropriate simulation software, to run both analytical and computational simulations optimized for the respective use case. The results of each of the multi-physics simulations are provided as input to a Simulation Discriminator Agent (also referred to as a Simulation Discriminating Agent) that is optimized for critiquing the CAD model design based on the simulation outputs. The Simulation Discriminator Agent evaluates the CAD model's response to various phenomena such as a change in externally applied loading, substation of material properties, or environmental temperature variations. The Simulation Discriminator Agent may generate feedback for the Modeling Agent to implement any changes needed to optimize the design for the CAD model. For example, if the Criterion Agent determines that the object that corresponds to the CAD model will be used in potentially explosive environments, the Simulation Discriminator Agent recommends or suggests an explicit numerical modeling approach for the pressure waves in the structure and gases when performing the analysis. The Modeling Agent can use the new results or output (feedback) provided by the Simulation Discriminator Agent to update or re-model the CAD model. The entire system and interactions between the agents of the present disclosure operate in an iterative loop, where each agent refines its own output based on the feedback from other agents. This process continues until the Simulation Discriminator Agent accepts the design(s) ensuring that the final CAD model is optimized for both form and function. The iterative nature of the system of the present disclosure allows for continuous improvement and adaptation to changing requirements.

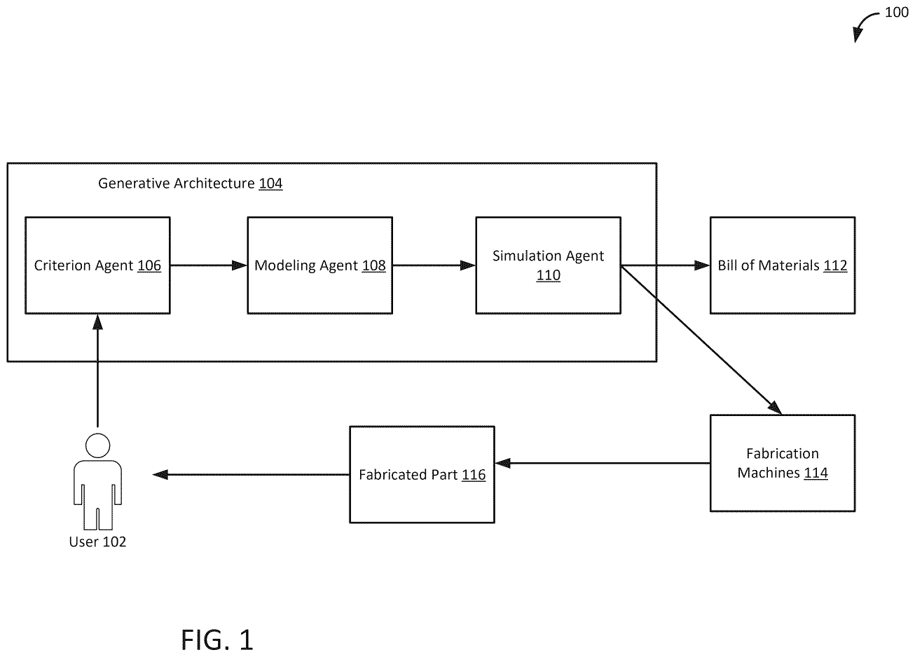

FIG. 1 illustrates an example architecture 100 for parametric computer-aided design (CAD) modeling using an Agentic Architecture according to embodiments described herein. The architecture 100 includes a user 102 interacting with the generative architecture 104 and in particular with the Criterion Agent 106 to provide requirements, input, information, etc., associated with an object that the user 102 wants to generate, create, refine, or optimize. For example, the user 102 may provide text input, image input, two-dimensional (2D) drawings, such as engineering drawings, requirements, specifications, need for an application of the object, etc., to the Criterion Agent 106. In embodiments, the Criterion Agent 106 may engage with the user 102 using an interactive chat which may be an example of a generative artificial intelligence (AI) chatbot that is configured to interact with the user 102, obtain input such as text or images, and provide queries, responses, or output other images to obtain the information for generating the modeling plan by the Modeling Agent 108.

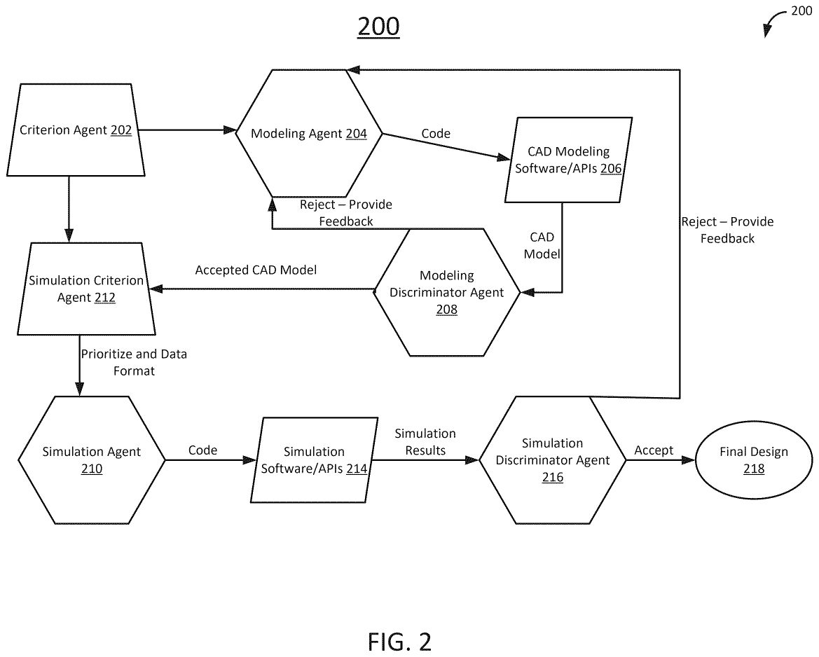

The Modeling Agent 108 may be configured to parametrically design a component or object which corresponds to the input or information provided by the user 102. For example, the Modeling Agent 108 may use the input or information from the Criterion Agent 106 to generate a modeling plan for an object that includes code (deterministic or executable code) for use by geometric modeling software such as CAD modeling software, SolidWorks, Z Direction, etc. The Modeling Agent 108 may interact with other agents, described in more detail with reference to FIG. 2 below, to generate an updated CAD model free from defects or errors. The Simulation Agent 110 may generate simulation boundary conditions for multi-physics simulations based on the updated CAD model and information from the Criterion Agent 106 which can then in turn be used to generate simulation code for a simulation software to execute a numerical analysis based on the simulation boundary conditions to generate results which can identify functional defects in the updated CAD model. This process is also described in more detail with reference to FIG. 2 below. In embodiments, the Simulation Agent 110 can determine important or salient parameters (simulation boundary conditions) for multi-physics simulations for the updated CAD model, and corresponding object, using the updated CAD model and the information from the Criterion Agent 106. For example, for marine related objects water pressure, salt levels in the atmosphere or environment, pH levels, etc., may be important to consider for the simulation boundary conditions. As another example, for electrical engineering objects the simulation boundary conditions may corresponds to parameters for which voltage ranges need to be tested or amperages.

The architecture 100 includes the generative architecture 104 generating a bill of materials 112 based on a refined or optimized CAD model that corresponds to an object based on the results obtained by the Simulation Agent 110. The bill of materials 112 may be used by providers, industrial providers, building manufacturers, etc., to order materials or components for building the object that corresponds to the optimized CAD model generated by the generative architecture 104. In embodiments, the generative architecture 104 can also provide instructions directly to one or more fabrication machines 114 for directly generating or creating the object that corresponds to the optimized CAD model. For example, the generative architecture 104 may identify or determine certain fabrication machines 114 that are needed to make a particular object that corresponds to the optimized CAD model and generate instructions to begin processing or fabricating parts to assemble the object which include certain requirements or parameters as identified in the optimized CAD model. The fabricated part 116 may then be provided to the user 102 after fabrication. In embodiments, the generative architecture 104 and the agents 106-110 may be implemented by a single computer system, multiple computer systems in communication with each other, or in a cloud environment. The system implementing the generative architecture 104 may be in communication with one or more systems or components such as external entities for fulfilling the bill of materials 112 or for fabricating an object such as fabricating machines 114 via wireless communication, wired communication, or the Internet.

FIG. 2 illustrates an example architecture 200 for parametric computer-aided design (CAD) modeling using an Agentic Architecture including one or more agents according to embodiments described herein. The example architecture 200 includes a Criterion Agent 202 that may gather, receive, or obtain contextual information from various inputs, including but not limited to two-dimensional (2D) sketches, natural language descriptions, form submissions, technical drawings, application programming interface (API) data, user input/discussions, etc., and converts the contextual inputs into a unified representation. The unified representation may be a unified latent space, domain conversion to natural language, specific data structure, or other suitable representation. The Criterion Agent 202 may implement reasoning paradigms to accomplish this goal and ensure that all criteria provided as input reflect a real-world use case that is aligned with user requirements. The Criterion Agent 202 may be implemented as a natural language interface. In some embodiments, the Criterion Agent 202 may receive audio input that is converted to natural language input by the Criterion Agent 202. In embodiments, the Criterion Agent 202 may determine geometric dimensions and relations for a CAD modeling process for an object based on the information obtained from a user or from one or more sources. For example, the relations may include mathematical relationships between different geometric elements. Relations may define how elements of an object are connected and how changes to one element affects other elements. For example, if the information provided to the Criterion Agent 202 corresponds to a shaft object, if the shaft diameter increases, so does the inner diameter of the pulley that is mounted to the shaft.

In embodiments, a Modeling Agent 204 may receive the unified data structure from the Criterion Agent 202. The Modeling Agent 204 may then employ various reasoning paradigms such as Reasoning+Acting (ReACT), Chain of Thought (CoT), and Tree-of-Thought reasoning paradigms to generate a step-by-step sequential modeling plan. The advanced reasoning paradigms enable the Modeling Agent 204 to reason through complex scenarios and make informed design decisions. The Modeling Agent 204 may then execute the modeling plan in a virtual environment using CAD modeling libraries and API calls, ensuring that the model is generated with best practices. For example, an LLM implementing the Modeling Agent 204 may be domain adapted to a respective organization's best modeling procedures, through continued-pre-training (CPT), and/or supervised fine-tuning (SFT), for a parametric and easily editable model. The modeling plan generated by the Modeling Agent 204 may include code for geometric modeling software. The architecture 200 includes the Modeling Agent 204 providing the modeling plan and code to the geometric modeling software, represented as CAD Modeling Software/APIs 206 in FIG. 2, for generating a CAD model for the object using the generated code. Although FIG. 2 depicts the use of a CAD Modeling Software/APIs 206, the embodiments disclosed herein are not limited to CAD software and other applicable software suites (e.g. geometric modeling software) may be used to generate the CAD model for the object.

The generated 3D model (CAD model) may then be provided as input to a Modeling Discriminator Agent 208 that is also implemented by an LLM optimized (again via CPT/SFT, prompt engineering, and/or structured output (grammars)) for critiquing 3D parametric CAD models (e.g., the received CAD model). The Modeling Discriminator Agent 208 may interpret or analyze the CAD model through a reasoning paradigm while recursively or hierarchically reasoning deeper as needed to provide critical feedback for the Modeling Agent 204 regarding geometric accuracy, structural integrity, adherence to design specifications, etc., (e.g. identify defects or errors in the CAD model). The generating and discriminating process continues iteratively in a similar fashion to generative adversarial networks (GANs) but for a reasoning task until the Modeling Discriminator Agent 208 can no longer critique the Modeling Agent's 204 design. This is depicted as a feedback loop between the Modeling Discriminator Agent 208 and the Modeling Agent 204 that results in generating an updated modeling plan, by the Modeling Agent 204, in response to receiving the feedback from the Modeling Discriminator Agent 208. The updated modeling plan can be used by the CAD Modeling Software/APIs 206 to generate an updated CAD model that is then analyzed by the Modeling Discriminator Agent 208 to identify defects or errors in the updated CAD model.

The architecture 200 includes the Modeling Discriminator Agent's 208 validated design (i.e., accepted CAD model of FIG. 2) being provided to a Simulation Agent 210, which takes as input any additional requirements gathered by the Simulation Criterion Agent 212 or other input source and sets up the necessary multi-physics simulations including appropriate boundary conditions and parameters. This is also implemented through an internal reasoning paradigm that checks its own work while progressing. The simulation boundary conditions and parameters generated by the Simulation Criterion Agent 212 may be associated with external loading conditions (e.g., pressures, forces, moments, temperatures, displacement and rotation constraints, etc., of a component or object) based on the information from the Criterion Agent 202 and the accepted CAD model (updated CAD model from the Modeling Discriminating Agent 208).

The Simulation Agent 210 may then generate simulation code (code between Simulation Agent 210 and Simulation Software/APIs 214) for Simulation Software/APIs 214 based on the simulation boundary conditions and parameters from the Simulation Criterion Agent 212 and the updated CAD model. The Simulation Agent 210 may interact or otherwise communicate with the Simulation Software/APIs 214 to execute the simulation code (virtual code), including executing API calls to an appropriate simulation software, to run both analytical and computational simulations optimized for the respective use case. For example, the Simulation Agent 210 and the Simulation Software/APIs 214 may implement, execute, or run a numerical analysis using the simulation boundary conditions and parameters and the updated CAD model for the object to generate simulation results. The numerical analysis may include a static structural, dynamic, or modal Finite Element Analysis (FEA), Computational Fluid Dynamics (CFD), or thermal analysis. The simulation results of each of the multi-physics simulations are provided as input to the Simulation Discriminator Agent 216 that is optimized for critiquing the CAD model design based on the simulation outputs (simulation results) of the Simulation Software/APIs 214. In embodiments, the Simulation Discriminator Agent 216 evaluates the CAD model's response to various phenomena such as a change in externally applied loading, substation of material properties, or environmental temperature variations using the simulation results to identify functional defects in the updated CAD model. The functional defects identified by the Simulation Discriminator Agent 216 are different from the defects and errors identified by the Discriminating Modeling Agent 208. For example, functional defects may correspond to the design of the updated CAD model meeting its intended function, as derived from the Simulation Criterion Agent 212. The simulation executed by the Simulation Agent 210 and Simulation Software/APIs 214 may indicate that the design of the updated CAD model would yield when stressed or that it would experience fatigue cracking under prolonged cyclic loads, for example.

The Simulation Discriminator Agent 216 may generate feedback for the Modeling Agent 204 to implement any changes needed to optimize the design for the CAD model. The Modeling Agent 204 can use the new results or output (feedback) provided by the Simulation Discriminator Agent 216 to update or re-model the CAD model. The entire system and interactions between the agents of FIG. 2 operate in an iterative loop, where each agent refines its own output based on the feedback from other agents. This process continues until the Simulation Discriminator Agent 216 accepts the design(s) ensuring that the final CAD model (Final Design 218) is optimized for both form and function. The iterative nature of the system represented in FIG. 2 allows for continuous improvement and adaptation to changing requirements. In embodiments, the Criterion Agent 202, Modeling Agent 204, Modeling Discriminator Agent 208, Simulation Criterion Agent 212, Simulation Agent 210, and Simulation Discriminator Agent 216 may be pre-trained LLMs that are trained using training datasets to execute the tasks or processes described herein. Some of the agents, such as Modeling Agent 204 or Criterion Agent 202 may be updated based on feedback provided by other agents or from input provided by a user. In embodiments, the Criterion Agent 202, Modeling Agent 204, Modeling Discriminator Agent 208, Simulation Criterion Agent 212, Simulation Agent 210, and Simulation Discriminator Agent 216 may implement one or more reasoning paradigms to execute the tasks or processes associated with each agent and described herein as well as update each agent across iterations.

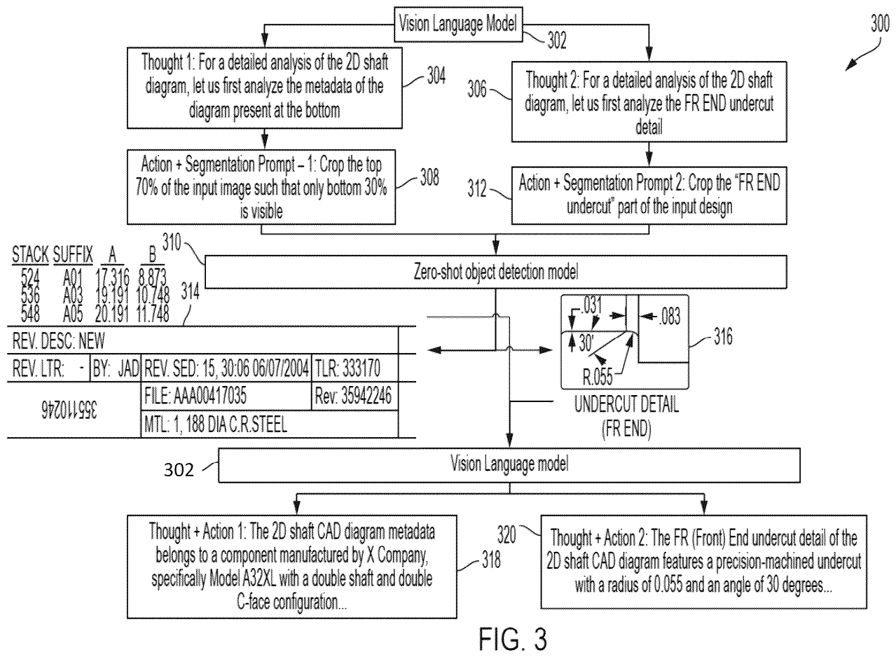

FIG. 3 illustrates an example flow chart 300 for implementing vision language models for the parametric computer-aided design (CAD) modeling using an Agentic Architecture according to embodiments described herein embodiments described herein. In flow chart 300, the Criterion Agent described herein may implement or be an example of a Vision Language Model 302 that is configured to receive and process images and/or text to generate natural language descriptions. The Vision Language Model 302 may generate descriptions for images, answer questions about images, find similarities between images and text descriptions, and/or automatically generate detailed descriptions from product images. The flowchart 300 of FIG. 3 depicts the Vision Language Model 302 extracting information from input sources to determine geometric dimensions and relations (engineering semantic relationships) for a CAD modeling process for an object. Flow chart 300 also depicts the Vision Language Model 302 (which may be implemented by the Criterion Agent) implementing or utilizing a reasoning paradigm to determine the geometric dimensions and relations (engineering semantic relationships) for a CAD modeling process for an object using input received from a user or from one or more sources. In embodiments, the LLM or Vision Language Model 302 may iterate through provided or obtained information using the reasoning paradigm to assess whether it has reached a logical conclusion to end the process. For example, the logical conclusion may be reached if a check of internal consistencies of a generated object has passed certain criteria. For example, the generated object geometry must not contain zero-volume or zero-thickness solid regions that can arise from self-intersecting sketch geometries. In some embodiments, the criterion to stop the information obtaining iterative process may be based on detecting a change from one thought iteration to the next and stopping the process if the changes become too insignificant. In an embodiment, the criterion to stop may be hard coded or include a user defined upper limit of thought tokens.

For example, FIG. 3 depicts two thought processes+action determinations that are determined by the Vision Language Model 302 and reasoning paradigm. Flow chart 300 includes at 304 a first thought and at 306 a second thought based on receiving a 2D shaft diagram. A first action is depicted at 308 based on first thought 304 for segmenting or cropping a portion of the provided 2D shaft diagram for further processing (e.g. object detection via a zero-shot objection detection model 310). FIG. 3 also depicts a second action at 312 based on second thought 306 for segmenting or cropping a portion of the provided 2D shaft diagram for further processing (e.g. object detection via a zero-shot objection detection model 310). FIG. 3 also depicts the cropped portions of the 2D shaft diagram using the action 308 at 314 and using the action 312 at 316. The flow chart 300 also depicts the iterative implementation of the vision language module 302 using the reasoning paradigm by generating two thoughts+action at 318 and 320 which may include specific instructions for further modification of the 2D shaft diagram or natural language descriptors of the portions of the 2D shaft diagram (314 and 316). The process depicted in FIG. 3 can continue until the Criterion Agent obtains the necessary or required geometric dimensions and relations for the CAD modeling process for the object.

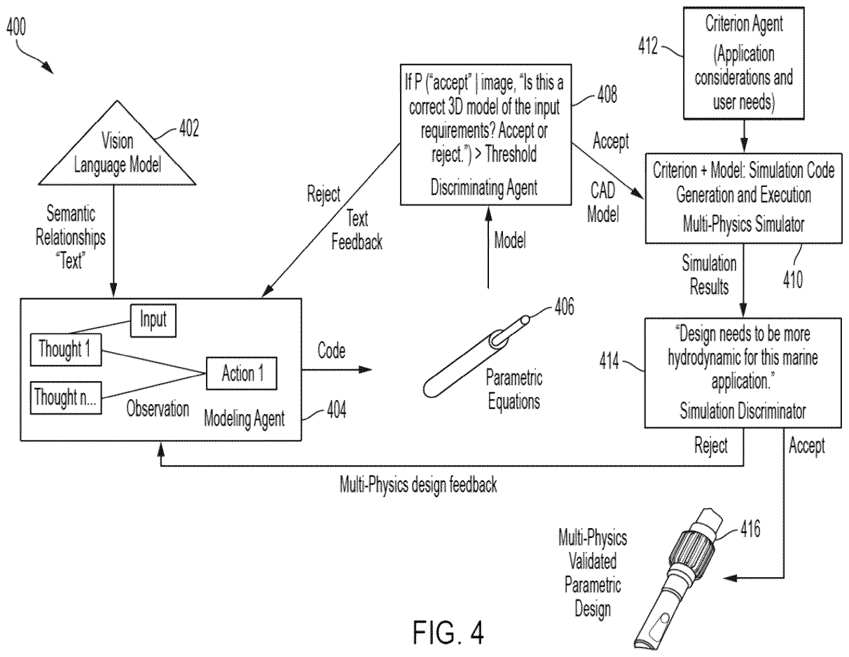

FIG. 4 illustrates an example architecture 400 for parametric computer-aided design (CAD) modeling using an Agentic Architecture and Finite Element Analysis (FEA) including one or more agents or modules according to embodiments described herein. Similar to FIG. 3, the Criterion Agent includes or utilizes a Vision Language Model 402 to determine semantic relationships, which may be represented as “text” that are provided to a Modeling Agent 404. The Modeling Agent 404 may implement or utilize reasoning paradigms, represented by input, thoughts 1 . . . N, for generating observations and determining actions (Action 1 of FIG. 4) for use in generating code. The code can be used by CAD modeling software/APIs (such as 206 of FIG. 2) for generating a CAD model for an object, such as shaft 406. The modeling plan that includes code for the geometric modeling software may include code as well as parametric equations for the CAD model for the object 406. As described herein, the CAD model may be provided to a Discriminating Agent 408 (Discriminating Modeling Agent) to identify defects or errors in the CAD model for object 406 and generate feedback for the Modeling Agent 404.

The Modeling Agent 404 and Discriminating Agent 408 may iterate several times to generate updated CAD models until the Discriminating Agent 408 accepts the updated CAD model which is then provided to a Multi-Physics Simulator 410. The Multi-Physics Simulator 410 may be an example of the Simulation Criterion Agent and Simulation Agent described herein. Architecture 400 of FIG. 4 includes the Multi-Physics Simulator 410 interacting with Criterion Agent 412 to receive application considerations and user needs which are used to generate simulation boundary conditions for multi-physics simulations. The Multi-Physics Simulator 410 may then generate and execute simulation code, via a simulation software, to execute a numerical analysis based on the simulation boundary conditions for generating simulation results. The numerical simulation in the Multi-Physics Simulator 410 may be implemented using the finite element method or other similar numerical methods. The simulation results may be provided to the Simulation Discriminator 414 (which may be an example of the Discriminating Simulation Agent described herein). The Simulation Discriminator 414 may be configured to identify functional defects on the updated CAD model based on the simulation results. The functional defects, which are represented as Multi-Physics design feedback, may be provided to the Modeling Agent 404 to generate updated code and a further updated CAD model. This process also executes iteratively until the Simulation Discriminator 414 no longer identifies functional defects in the simulation results using the updated CAD model resulting in a multi-physics validated parametric design (accepted CAD model or design) 416.

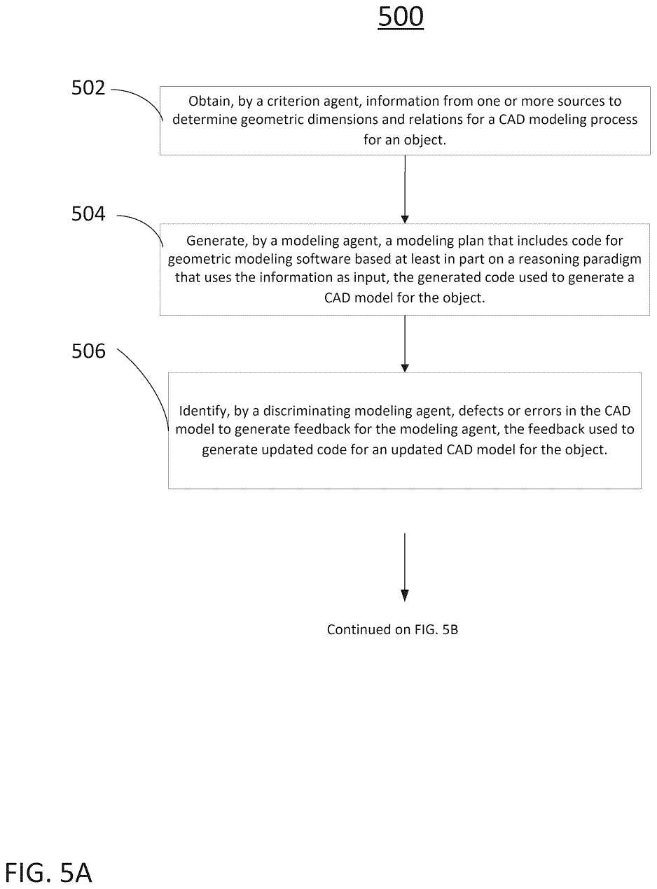

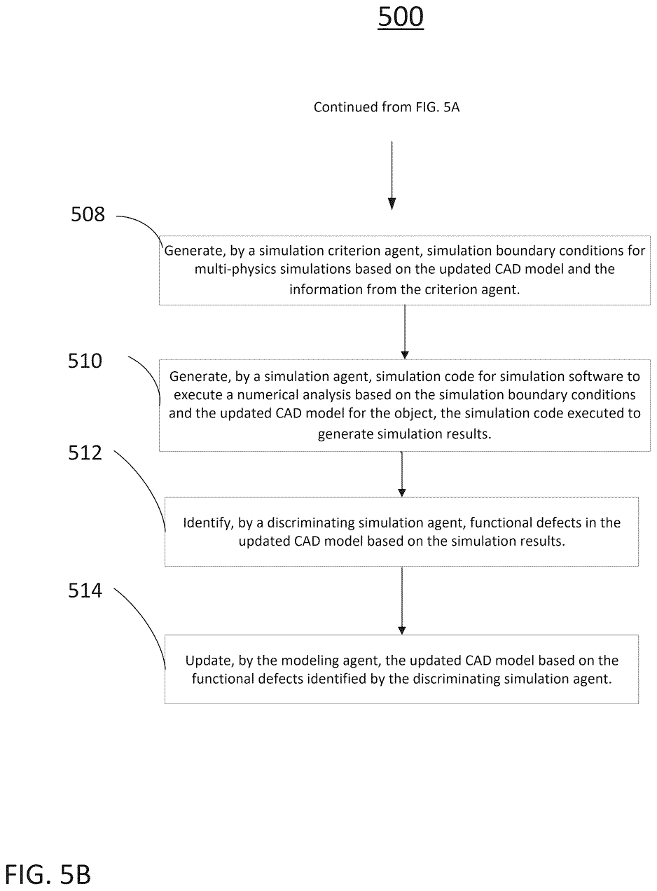

FIGS. 5A and 5B illustrate a flow chart for parametric computer-aided design (CAD) modeling using an Agentic Architecture according to embodiments described herein. FIGS. 5A and 5B include an exemplary process 500 which may be performed by an environment or architecture such as in FIGS. 1-4 and by systems and components of FIGS. 1-4 and 6. However, it will be recognized that any of the following blocks may be performed in any suitable order and that the process 500 may be performed in any environment or architecture and by any suitable computing device and/or controller.

At step 502, the process 500 includes obtaining, by a criterion agent, information from one or more sources to determine geometric dimensions and relations for a CAD modeling process for an object. For example, the one or more sources may include text, images, technical drawings, forms, parameters, or metrics obtained by a user (e.g. provided by a user in a file or by interacting with a user interface) or from one or more databases in communication with a computer system implementing the features described herein. The parameters or metrics may not be from a user directly and instead correspond to data from a 3D scanner, or measurement points or scan data from a coordinate measuring machine (CMM). In some embodiments, the criterion agent obtains the information from a user via an interactive chat with the user that is generated and iteratively updated by the criterion agent in response to receiving user provided input. The interactive chat may be an example of a generative artificial intelligence (AI) chatbot that is configured to interact with the user, obtain input such as text or images, and provide queries, responses, or output other images to obtain the information for generating the modeling plan by the modeling agent. At step 504, the process 500 includes generating, by a modeling agent, a modeling plan that includes code for geometric modeling software based at least in part on a reasoning paradigm that uses the information as input, where the generated code is used to generate a CAD model for the object. In embodiments, the modeling agent may generate the modeling plan that includes code for the geometric modeling software by implementing reasoning paradigms including Reasoning+Acting (ReACT), Chain of Thought (CoT), and Tree-of-Thought reasoning paradigms or other suitable reasoning paradigms for generating modeling plans for CAD models.

At step 506, the process 500 includes identifying, by a discriminating modeling agent, defects or errors in the CAD model to generate feedback for the modeling agent, where the feedback can be used to generate updated code for an updated CAD model for the object. In embodiments, the modeling agent may be updated based on the feedback such that subsequent modeling plans do not include the same identified defects or errors. For example, the modeling agent may update the modeling plan and generating updated code for the geometric modeling software in response to receiving the feedback from the discriminating modeling agent to generate an updated CAD model for the object. In embodiments, updating the CAD model is executed or performed iteratively until the discriminating model agent does not identify the defects or errors in the updated CAD model.

At step 508, the process 500 includes generating, by a simulation criterion agent, simulation boundary conditions for multi-physics simulations based on the updated CAD model and the information from the criterion agent. At step 510, the process 500 includes generating, by a simulation agent, simulation code for simulation software to execute a numerical analysis based on the simulation boundary conditions and the updated CAD model for the object, where the simulation agent may generate simulation results by executing the simulation code via the simulation software. At step 512, the process 500 includes identifying, by a discriminating simulation agent, functional defects in the updated CAD model based on the simulation results. At step 514, the process 500 includes updating, by the modeling agent, the updated CAD model based on the functional defects identified by the discriminating simulation agent. In embodiments, updating the updated CAD model is performed iteratively until the discriminating simulation agent does not identify the functional defects in the updated CAD model based on the simulation results. In some embodiments, the simulation agent is updated based on the identified functional defects in the updated CAD model. As described herein, the criterion agent, the modeling agent, the discriminating modeling agent, the simulation criterion agent, the simulation agent, and the discriminating simulation agent are each a separate large langue model (LLM) or vision language model (VLM). The system implementing the features described herein may instruct one or more fabrication process machines to generate the object using the updated CAD model. Updating, by the modeling agent, the updated CAD model based on the functional defects identified by the discriminating simulation agent includes changing parameters, data points, or measurements in a file corresponding to the updated CAD model. This may result in generating a new CAD model or updated CAD model that is saved to memory or storage for further processing or for use in fabricating an associated object by instructing one or more fabrication machines using the parameters, dimensions, or data included in the updated CAD file.

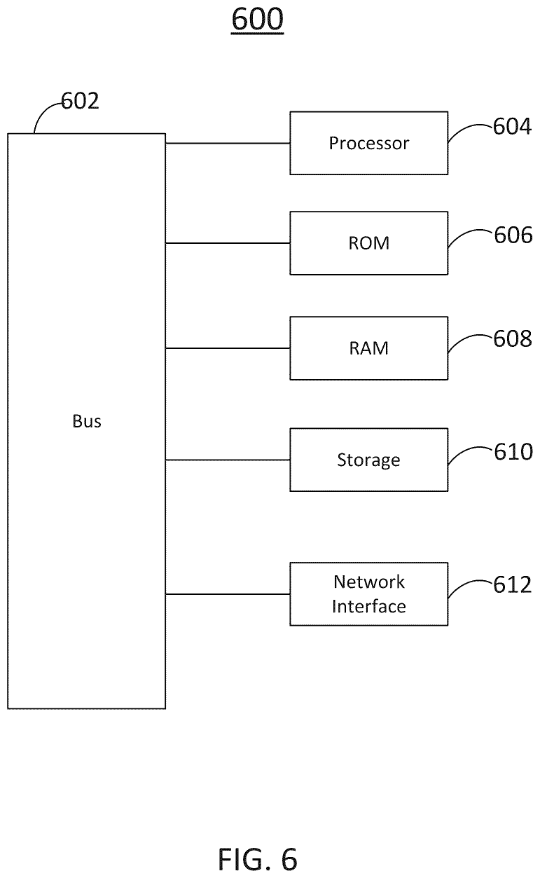

FIG. 6 illustrates a simplified block diagram of one or more devices or systems for parametric computer-aided design (CAD) modeling using an Agentic Architecture according to embodiments of the present disclosure. FIG. 6 is a block diagram of an exemplary system or device 600 associated with a machine, or otherwise integrated with a machine such as machines for operating automated processes and/or associated with a manufacturing system or one or more fabrication process machines. Fabrication process machines may include relevant computer numerical control (CNC) equipment such as milling centers, lathes, laser cutters, water jets, surface grinders, heat treat ovens, broaching machines, 3D printers, etc. The system 600 includes a processor 604, such as a central processing unit (CPU), and/or logic, that executes computer executable instructions for performing the functions, processes, and/or methods described herein. In some examples, the computer executable instructions are locally stored and accessed from a non-transitory computer readable medium, such as storage 610, which may be a hard drive or flash drive. Read Only Memory (ROM) 606 includes computer executable instructions for initializing the processor 604, while the random-access memory (RAM) 608 is the main memory for loading and processing instructions executed by the processor 604.

The network interface 612 may connect to a wired network or cellular network and to a local area network or wide area network. The system 600 may also include a bus 602 that connects the processor 604, ROM 606, RAM 608, storage 610, and/or the network interface 612. The components within the system 600 may use the bus 602 to communicate with each other. The components within the system 600 are merely exemplary and might not be inclusive of every component for embodiments described herein. For instance, in some examples, the system 600 might not include a network interface 612. In embodiments the system 600 may include one or more components for interacting with a machine or system executing an automated process such as actuators, output devices (e.g., speakers or user interfaces), power convertors or power supply systems. The system may use the one or more components for executing an action in response to generating or updating a CAD model such as instructing fabrication process machines to fabricate, print, mold, or take another actin for generating an object that corresponds to the updated CAD model, present the updated CAD model via a user interface, or otherwise start or cease operation of one or more machines (fabrication process machines). In embodiments the network interface 612 may communicate with one or more machines, computers, or systems within a facility or industrial environment to obtain operating data, test data, and/or model files for fabricating or generating an object that corresponds to the updated CAD model.

While the disclosure has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present disclosure covers further embodiments with any combination of features from different embodiments described above and below. Additionally, statements made herein characterizing the disclosure refer to an embodiment of the disclosure and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A computer-implemented method for parametric computer-aided design (CAD) modeling using an Agentic Architecture implemented by one or more processors, the method comprising:
obtaining, by a criterion agent, information from one or more sources to determine geometric dimensions and relations for a CAD modeling process for an object;
generating, by a modeling agent, a modeling plan that includes code for geometric modeling software based at least in part on a reasoning paradigm that uses the information as input, the generated code used to generate a CAD model for the object;
identifying, by a discriminating modeling agent, defects or errors in the CAD model to generate feedback for the modeling agent, the feedback used to generate updated code for an updated CAD model for the object;
generating, by a simulation criterion agent, simulation boundary conditions for multi-physics simulations based on the updated CAD model and the information from the criterion agent;
generating, by a simulation agent, simulation code for simulation software to execute a numerical analysis based on the simulation boundary conditions and the updated CAD model for the object, the simulation code executed to generate simulation results;
identifying, by a discriminating simulation agent, functional defects in the updated CAD model based on the simulation results; and
updating, by the modeling agent, the updated CAD model based on the functional defects identified by the discriminating simulation agent.

2. The computer-implemented method according to claim 1, further comprising:
updating, by the modeling agent, the modeling plan and generating the updated code for the geometric modeling software in response to receiving the feedback from the discriminating modeling agent to generate the updated CAD model for the object, wherein the simulation agent generates the simulation results by executing the simulation code via the simulation software, and wherein updating the CAD model is performed iteratively until the discriminating model agent does not identify the defects or errors in the updated CAD model.

3. The computer-implemented method according to claim 2, wherein updating the updated CAD model is performed iteratively until the discriminating simulation agent does not identify the functional defects in the updated CAD model based on the simulation results.

4. The computer-implemented method according to claim 1, further comprising updating the modeling agent based on the feedback and the simulation agent based on the identified functional defects in the updated CAD model.

5. The computer-implemented method according to claim 1, wherein the criterion agent, the modeling agent, the discriminating modeling agent, the simulation criterion agent, the simulation agent, and the discriminating simulation agent are each a separate large langue model (LLM) or vision language model (VLM).

6. The computer-implemented method according to claim 1, wherein the one or more sources includes text, images, technical drawings, forms, parameters, or metrics obtained by a user or from one or more databases.

7. The computer-implemented method according to claim 6, wherein the criterion agent is configured to obtain the information from the user via an interactive chat generated and iteratively updated by the criterion agent in response to receiving user provided input.

8. The computer-implemented method according to claim 1, wherein the modeling agent generates the modeling plan that includes the code for the geometric modeling software by implementing reasoning paradigms.

9. The computer-implemented method according to claim 8, wherein the reasoning paradigms include Reasoning+Acting (ReACT), Chain of Thought (CoT), and Tree-of-Thought reasoning paradigms.

10. The computer-implemented method according to claim 1, further comprising instructing one or more fabrication process machines to generate the object using the updated CAD model.

11. The computer-implemented method according to claim 2, wherein updating, by the modeling agent, the updated CAD model based on the functional defects identified by the discriminating simulation agent includes changing parameters, data points, or measurements in a file corresponding to the updated CAD model.

12. A computer system for parametric computer-aided design (CAD) modeling using an Agentic Architecture, the computer system comprising one or more hardware processors which, alone or in combination, are configured to provide for execution of the following steps:
generating, by a modeling agent, a modeling plan that includes code for geometric modeling software based at least in part on a reasoning paradigm that uses information as input, the information obtained from one or more sources and identifying geometric dimensions and relations for a CAD modeling process for an object;
generating a CAD model for the object using the generated code;
identifying, by a discriminating modeling agent, defects or errors in the CAD model to generate feedback for the modeling agent;
updating, by the modeling agent, the modeling plan and generating updated code for the geometric modeling software in response to receiving the feedback from the discriminating modeling agent to generate an updated CAD model for the object;
generating, by a simulation criterion agent, simulation boundary conditions for multi-physics simulations based on the updated CAD model and the information from the criterion agent;
generating, by a simulation agent, simulation code for simulation software to execute a numerical analysis based on the simulation boundary conditions and the updated CAD model for the object;
generating, by the simulation agent, simulation results by executing the simulation code via the simulation software;
identifying, by a discriminating simulation agent, functional defects in the updated CAD model based on the simulation results; and
updating, by the modeling agent, the updated CAD model based on the functional defects identified by the discriminating simulation agent.

13. The computer system according to claim 12, wherein updating the CAD model is performed iteratively until the discriminating model agent does not identify the defects or errors in the updated CAD model.

14. The computer system according to claim 12, wherein updating the updated CAD model is performed iteratively until the discriminating simulation agent does not identify the functional defects in the updated CAD model based on the simulation results.

15. The computer system according to claim 12, further comprising updating the modeling agent based on the feedback and the simulation agent based on the identified functional defects in the updated CAD model.

16. The computer system according to claim 12, wherein the one or more sources includes text, images, technical drawings, forms, parameters, or metrics obtained by a user or from one or more data bases.

17. The computer system according to claim 12, wherein the modeling agent generates the modeling plan that includes the code for the geometric modeling software by implementing reasoning paradigms.

18. A tangible, non-transitory computer-readable medium having instructions thereon which, upon being executed by one or more processors, provide for parametric computer-aided design (CAD) modeling using an Agentic Architecture by execution of the following steps:
obtaining, by a criterion agent, information from one or more sources to determine geometric dimensions and relations for a CAD modeling process for an object;
generating, by a modeling agent, a modeling plan that includes code for geometric modeling software based at least in part on a reasoning paradigm that uses the information as input;
generating a CAD model for the object using the generated code;
identifying, by a discriminating modeling agent, defects or errors in the CAD model to generate feedback for the modeling agent;
updating, by the modeling agent, the modeling plan and generating updated code for the geometric modeling software in response to receiving the feedback from the discriminating modeling agent to generate an updated CAD model for the object;
generating, by a simulation agent, simulation code for simulation software to execute a numerical analysis based on simulation boundary conditions and the updated CAD model for the object, the simulation boundary conditions being for multi-physics simulations based on the updated CAD model and the information from the criterion agent;
generating, by the simulation agent, simulation results by executing the simulation code via the simulation software;
identifying, by a discriminating simulation agent, functional defects in the updated CAD model based on the simulation results; and
updating, by the modeling agent, the updated CAD model based on the functional defects identified by the discriminating simulation agent.

19. The tangible, non-transitory computer-readable medium according to claim 18, wherein the instructions, upon being executed by the one or more processors, are further configured to execute the following steps updating the modeling agent based on the feedback and the simulation agent based on the identified functional defects in the updated CAD model.

20. The tangible, non-transitory computer-readable medium according to claim 19, wherein the instructions, upon being executed by the one or more processors, are further configured to execute the following steps instructing one or more fabrication process machines to generate the object using the updated CAD model.
